(19) United States
(12) Patent Application Publication
(10) Pub. No.: US 2018/0114710 A1
(43) Pub. Date: Apr. 26, 2018

(54) EQUIPMENT FRONT END MODULE AND SEMICONDUCTOR MANUFACTURING APPARATUS INCLUDING THE SAME

(71) Applicant: SAMSUNG ELECTRONICS CO., LTD., Suwon-si (KR)

(72) Inventors: Jae-in JEONG, Yongin-si (KR); Eun-young HAN, Hwaseong-si (KR); Ae-kyoung NA, Seoul (KR)

(21) Appl. No.: 15/649,941

(22) Filed: Jul. 14, 2017

(30) Foreign Application Priority Data
Oct. 25, 2016 (KR) 10-2016-0139282

(51) Int. Cl. H01L 21/67; H01L 21/677; H01L 21/687; H01L 21/673

(52) U.S. Cl. CPC H01L 21/67201; H01L 21/673; H01L 21/68707; H01L 21/67763

(57) ABSTRACT

A semiconductor manufacturing apparatus includes an equipment front end module (EFEM) including a chamber having an inner space that accommodates a wafer container storing a plurality of wafers, the EFEM adjusting the inner space to first vacuum pressure or atmospheric pressure; and manufacturing process equipment configured to transfer a wafer in the wafer container to a process chamber that performs a manufacturing process of a wafer, and transfer a wafer, after the manufacturing process has been completed, in the process chamber to the wafer container.

### CROSS-REFERENCE TO RELATED APPLICATION

Korean Patent Application No. 10-2016-0139282, filed on Oct. 25, 2016, in the Korean Intellectual Property Office, and entitled: “Equipment Front End Module And Semiconductor Manufacturing Apparatus Including the Same,” is incorporated by reference herein in its entirety.

### BACKGROUND

### 1. Field

Embodiments relate to an equipment front end module (EFEM) and a semiconductor manufacturing apparatus including the EFEM.

### 2. Description of the Related Art

A process of manufacturing a semiconductor device is performed by various unit processes that are sequentially performed and wafers are transferred between pieces of process equipment each performing a unit process.

### SUMMARY

Embodiments are directed to a semiconductor manufacturing apparatus, including an equipment front end module (EFEM) including a chamber having an inner space that accommodates a wafer container in which a plurality of wafers are storeable, the EFEM adjusting the inner space to first vacuum pressure or atmospheric pressure, and manufacturing process equipment configured to transfer a wafer from the wafer container to a process chamber in which a manufacturing process of the wafer is performed, and transfer the wafer, after the manufacturing process has been completed, from the process chamber to the wafer container.

Embodiments are also directed to an equipment front end module (EFEM) including a chamber having an inner space that accommodates a wafer container in which a plurality of wafers is storable, a first door opening and closing between manufacturing process equipment and the chamber, and opening in such a manner that a wafer in the wafer container is directly carried out to the manufacturing process equipment or directly carried into the wafer container from the manufacturing process equipment, a second door opened/closed such that the inner space is exposed to the outside, or opened such that the wafer container is carried in or carried out, a vacuum pump configured to exhaust gas in the inner space through an exhaust port of the chamber, and a gas supply configured to inject purge gas into the inner space such that the inner space is in an atmospheric pressure state.

Embodiments are also directed to an equipment front end module (EFEM), including a wafer container chamber, the wafer container chamber being configured to receive a wafer container that contains a plurality of wafers, a wafer container door, the wafer container door opening and closing the wafer container chamber to an ambient atmosphere, the wafer container door passing the wafer container therethrough into and out of the wafer container chamber, and a wafer door, the wafer door opening and closing the wafer container chamber to a process equipment, the wafer door passing a wafer from the wafer container therethrough into and out of the wafer container. The wafer container may be configured to maintain an atmospheric pressure different from the ambient atmosphere and different from the process equipment.

### BRIEF DESCRIPTION OF THE DRAWINGS

Features will become apparent to those of skill in the art by describing in detail example embodiments with reference to the attached drawings in which:

FIG. 1 illustrates a plan view of a semiconductor manufacturing apparatus according to an example embodiment;

FIG. 2 illustrates a cross-sectional view of a semiconductor manufacturing apparatus according to an example embodiment;

FIG. 3 illustrates a perspective view of an equipment front end module (EFEM) according to an example embodiment, in which a part of a chamber is removed;

FIG. 4 illustrates a flowchart of an operation method of a semiconductor manufacturing apparatus according to an example embodiment;

FIG. 5 illustrates a graph showing pressure change in an EFEM at each operation of the operation method of the semiconductor manufacturing apparatus of FIG. 4;

FIG. 6 illustrates a graph showing humidity change in a wafer container when the wafer container is exposed to external air in an atmospheric pressure state after awaiting in an EFEM;

FIG. 7 illustrates a cross-sectional view showing a process of loading or unloading a wafer container into or from an EFEM through a ceiling transferring device, according to an example embodiment;

FIG. 8 illustrates a cross-sectional view showing a process of loading or unloading a wafer container into or from an EFEM through a ceiling transferring device, according to an example embodiment;

FIG. 9 illustrates a plan view of a semiconductor manufacturing apparatus according to an example embodiment;

FIG. 10 illustrates a flowchart of an operation method of a semiconductor manufacturing apparatus according to an example embodiment; and

FIG. 11 illustrates a graph showing pressure change in an EFEM at each operation of the operation method of the semiconductor manufacturing apparatus of FIG. 10.

### DETAILED DESCRIPTION OF THE EMBODIMENTS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

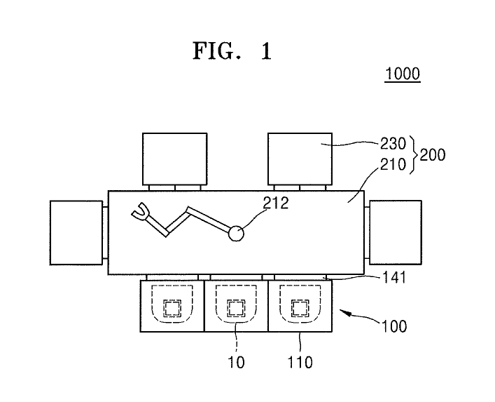

FIG. 1 is a plan view of a semiconductor manufacturing apparatus 1000 according to an example embodiment.

Referring to FIG. 1, the semiconductor manufacturing apparatus 1000 may include an equipment front end module (EFEM) 100 and manufacturing process equipment 200.

The semiconductor manufacturing apparatus 1000 may have a cluster system capable of processing a plurality of wafers (substrates). The cluster system may be a multi-chambered substrate processing system including a transfer robot 212 and a plurality of substrate process modules provided around the transfer robot 212.

The EFEM 100 may hold a wafer container 10. The wafer container 10 may be loaded into the EFEM 100 and may be unloaded from the EFEM 100 after a manufacturing process of a wafer has been completed. The wafer container 10 may await or remain in the EFEM 100 until the manufacturing process of a wafer has been completed.

The wafer container 10, which stores semiconductor substrates such as a wafer, may use an enclosed front-opening unified pod (FOUP) to prevent a wafer from being contaminated by foreign materials in the air or chemicals during transfer of the wafer.

The EFEM 100 may include a chamber 110 providing an inner space 111 where the wafer container 10 is held. The EFEM 100 may include a plurality of chambers 110 to accommodate a plurality of wafer containers 10, respectively.

The EFEM 100 may maintain internal pressure by intersecting a vacuum state and an atmospheric pressure state to prevent pressure change in the manufacturing process equipment 200.

In more detail, the EFEM 100 may maintain pressure of the inner space 111 at atmospheric pressure while the wafer container 10 is loaded/unloaded into/from the EFEM 100. The EFEM 100, in order to boost vacuum pressure in the inner space 111 of the chamber 110 and the wafer container 10 to atmospheric pressure, may fill the inner space 111 and the wafer container 10 with, for example, nitrogen gas, inert gas, or clean-dry air (CDA). Also, the EFEM 100 may maintain pressure of the inner space 111 at vacuum pressure during a manufacturing process of a wafer. The EFEM 100 may forcibly exhaust gas of the inner space 111 to decompress atmospheric pressure of the inner space 111 of the chamber 110 to vacuum pressure.

Here, vacuum pressure may be lower than atmospheric pressure. In some example embodiments, vacuum pressure may approximately be the same as internal pressure of a transfer chamber 210. For example, vacuum pressure may be a pressure of 100 Torr or less. Furthermore, vacuum pressure may be a pressure of 10 Torr or less or may be a pressure of 10⁻³ Torr or less.

The manufacturing process equipment 200 may be disposed in the rear of the EFEM 100, and may include the transfer chamber 210 and a process chamber 230. The manufacturing process equipment 200 may be, for example, dry etch equipment, chemical vapor deposition (CVD) equipment, a thermal furnace, developing equipment, cleaning equipment, etc.

The transfer chamber 210 may be disposed between the EFEM 100 and the process chamber 230. The transfer chamber 210 may provide the freely rotatable transfer robot 212, and may transfer a wafer between the process chamber 230 and the wafer container 10 awaiting in the EFEM 100.

The process chamber 230 may perform a manufacturing process of a wafer. An entrance gate 301, through which a wafer is carried in or carried out, may be disposed between the process chamber 230 and the transfer chamber 210. The process chamber 230 may be plural along each side of the transfer chamber 210.

After a manufacturing process of a wafer has been completed in the process chamber 230, the wafer may be transferred to the wafer container 10 awaiting in the EFEM 100 by the transfer robot 212 of the transfer chamber 210. The inside of the wafer EFEM 100 may be maintained in a vacuum state while the wafer is stored in the wafer container 10. The wafer, after the manufacturing process has been completed, may remain in the EFEM 100 in a vacuum state until the wafer container 10 is unloaded. Thus, residual gas or moisture on the wafer may be removed.

In addition, a residual contaminant on the wafer, after the manufacturing process has been completed, may be removed while the wafer awaits in the EFEM 100. Therefore, an unprocessed wafer in the wafer container 10 may be prevented from being contaminated by corrosive gas emitted from the wafer after the manufacturing process has been completed. Accordingly, the transfer robot 212 of the transfer chamber 210 may directly transfer a wafer from the process chamber 230 to the EFEM 100 without passing through a buffer chamber for separately storing the wafer after the manufacturing process has been completed.

According to the present example embodiment, the semiconductor manufacturing apparatus 1000 may perform a manufacturing process of a wafer in the manufacturing process equipment 200 maintaining a vacuum state, and make wafers, after the manufacturing process has been completed, await in the EFEM 100 in a vacuum state, and fill the wafer container 10 with purge gas before unloading the wafer container 10. Therefore, the semiconductor manufacturing apparatus 1000 may prevent a wafer from being exposed to external air, and may further prevent a wafer from being exposed to and contaminated by a contaminant in external air.

An unprocessed substrate to be processed in the semiconductor manufacturing apparatus 1000, for example, a wafer, may be a wafer for manufacturing a semiconductor circuit. In addition to the shown configuration of the semiconductor manufacturing apparatus 1000, a plurality of processing systems may be used to perform all processes for complete manufacture of an integrated circuit or a chip.

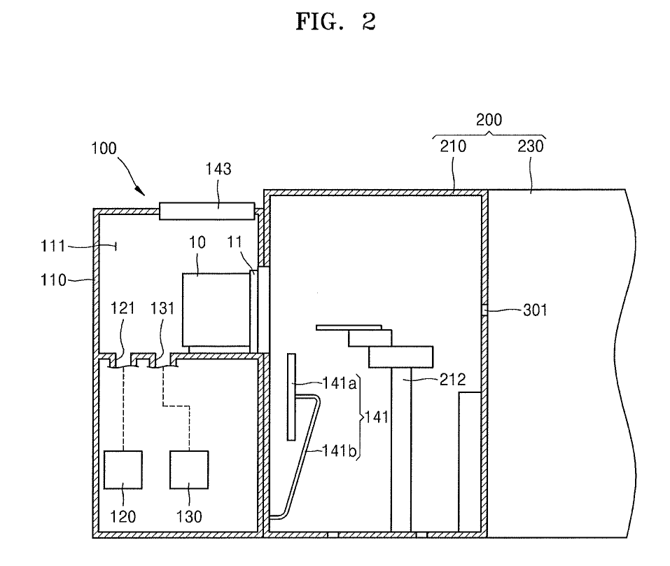

FIG. 2 is a cross-sectional view of the semiconductor manufacturing apparatus 1000 according to an example embodiment.

Referring to FIG. 2, the semiconductor manufacturing apparatus 1000 may include the EFEM 100 and the manufacturing process equipment 200 disposed in the rear of the EFEM 100 as described above. The EFEM 100 may include the chamber 110, a first door 141, a second door 143, a vacuum pump 120, and a gas supply 130.

The first door 141 may be disposed between the chamber 110 and the manufacturing process equipment 200, and may open and close an opening of the chamber 110. The first door 141 may be opened to carry out a wafer in an unprocessed state mounted on the wafer container 10 to the manufacturing process equipment 200 or to carry a wafer after a manufacturing process has been completed in the wafer container 10. The first door 141 may be closed to prevent a pressure state of the manufacturing process equipment 200 from being changed due to a pressure state of the inner space 111 of the chamber 110.

The second door 143 may be disposed to carry in or carry out the wafer container 10. For example, the second door 143 is disposed in an upper portion of the chamber 110 and may open and close the opening of the chamber 110. The second door 143 may be opened while the wafer container 10 is loaded into or unloaded from the EFEM 100. The second door 143 may be closed to isolate the inner space 111 of the chamber 110 from the outside.

The inner space 111 of the chamber 110 accommodating the wafer container 10 may be sealed by a closing operation of the first and second doors 141 and 143. Each of the first and second doors 141 and 143 may include, for example, a slit valve to maintain the inner space 111 in a sealed state.

The first door 141 may open a doorway 11 of the wafer container 10, opening or closing a front side of the wafer container 10. For example, the first door 141 may include a door holder 141a and an arm 141b. The door holder 141a may have a size and a shape corresponding to that of the doorway 11 of the wafer container 10 and may include an opening/closing device to lock or unlock the doorway 11 of the wafer container 10. The arm 141b may be connected and fixed to a rear side of the door holder 141a and may move the door holder 141a. The wafer container 10 may be joined with the first door 141 while the first door 141 closes the opening of the chamber 110, and the door holder 141a may fit and fix the doorway 11 after unlocking the doorway 11 of the wafer container 10. The door holder 141a may open the doorway 11 of the wafer container 10 from a main body of the wafer container 10 by being reversed.

The vacuum pump 120 may exhaust gas of the inner space 111 sealed by the closing operation of the first and second doors 141 and 143. The vacuum pump 120 may exhaust gas of the inner space 111 through an exhaust port 121 in the chamber 110. The vacuum pump 120 may be connected to the exhaust port 121 through an exhaust line, and a pressure-control valve and a flow-control valve may be disposed in the exhaust line. The inner space 111 and the inside of the wafer container 10 may be in a vacuum state as the vacuum pump 120 exhausts gas in the inner space 111.

The gas supply 130 may inject purge gas into the inner space 111 sealed by the closing operation of the first and second doors 141 and 143. For example, purge gas may be nitrogen gas, inert gas, or CDA. The gas supply 130 may supply purge gas to the inner space 111 through an injection port 131 in the chamber 110. The gas supply 130 may include a gas supply valve to adjust purge gas flow according to an electrical signal and various filters to remove foreign materials in the purge gas supplied to the inner space 111. As the gas supply 130 injects purge gas into the inner space 111, the inner space 111 and the inside of the wafer container 10 may be filled with purge gas and may be in an atmospheric pressure state.

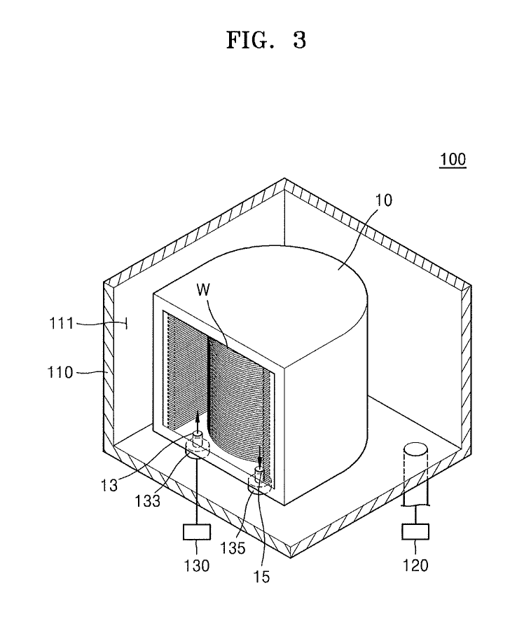

FIG. 3 is a perspective view of the EFEM 100 according to an example embodiment, in which a part of the chamber 110 is removed.

Referring to FIG. 3, the gas supply 130 may inject and fill purge gas into the inside of the wafer container 10. Although the doorway 11 (of FIG. 2) of the wafer container 10 is not shown in FIG. 3 for convenience of description, the front side of the wafer container 10 may be closed by the doorway 11 of the wafer container 10 while the wafer container 10 is filled with purge gas.

In more detail, the gas supply 130 may inject purge gas through a purge gas injection port 133 of the chamber 110 and an inlet port 13 of the wafer container 10, and may exhaust purge gas through a purge gas exhaust port 135 of the chamber 110 and an outlet port 15 of the wafer container 10. A purge nozzle may be disposed in the purge gas injection port 133 to inject purge gas into the wafer container 10 and to prevent backflow of purge gas. In addition, a purge nozzle may be disposed in the purge gas exhaust port 135 to exhaust gas in the wafer container 10 and to prevent gas backflow. The purge gas exhaust port 135 may be connected to an exhaust pump through an exhaust line.

The gas supply 130 may simultaneously inject purge gas into the inner space 111 of the chamber 110 and the wafer container 10, and thus, the inner space 111 and the wafer container 10 in a vacuum state may be boosted to pressure raised by being filled with purge gas, for example, atmospheric pressure.

When the wafer container 10 is unloaded from the EFEM 100, the gas supply 130 may prevent a wafer W stored in the wafer container 10 from being exposed to external air by filling the wafer container 10 with purge gas.

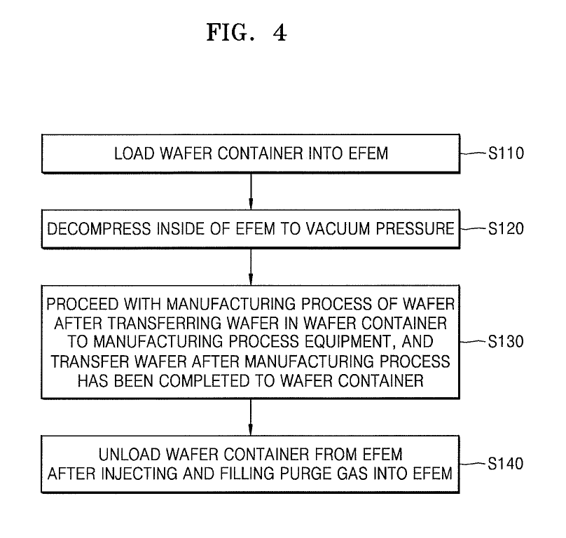

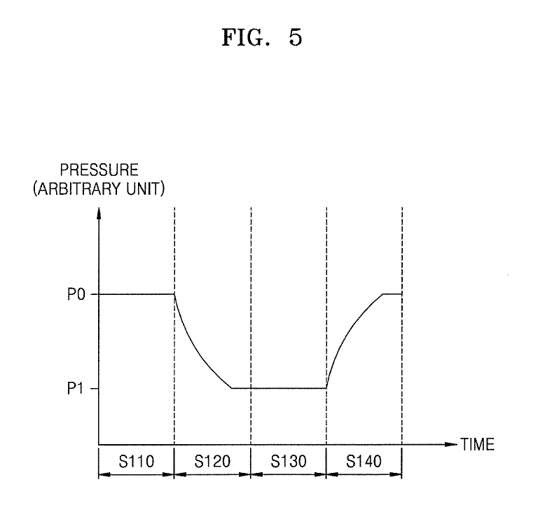

Hereinafter, with reference to FIGS. 4 and 5 as well as FIGS. 1 to 3, an operation method of the semiconductor manufacturing apparatus 1000 including the EFEM 100 will be described. FIG. 4 is a flowchart of an operation method of the semiconductor manufacturing apparatus 1000 according to an example embodiment. FIG. 5 is a graph showing pressure change in the EFEM 100 at each operation of the operation method of the semiconductor manufacturing apparatus 1000 of FIG. 4.

In operation S110, the wafer container 10 is loaded into the EFEM 100. The second door 143 is opened and the wafer container 10 is carried in the chamber 110. When the wafer container 10 is stably attached to the chamber 110, the inner space 111 of the chamber 110 is sealed by the second door 143 being closed. The inner space 111 may be in an atmospheric pressure P0 state while the wafer container 10 is loaded into the EFEM 100.

In operation S120, the inside of the EFEM 100 is decompressed to vacuum pressure P1. The vacuum pump 120 decompresses the inner space 111 from the atmospheric pressure P0 to the vacuum pressure P1 by exhausting gas in the inner space 111, and accordingly, the inside of the wafer container 10 may also be decompressed to the vacuum pressure P1. Next, the first door 141 may open a front side of the wafer container 10 by opening the doorway 11 of the wafer container 10.

In another embodiment, decompression by the vacuum pump 120 may be performed when the inner space 111 and the inside of the wafer container 10 are filled with purge gas and the doorway 11 of the wafer container 10 is opened by the first door 141.

In operation S130, a manufacturing process of a wafer proceeds after a wafer in the wafer container 10 is transferred to the manufacturing process equipment 200, and the wafer, after the manufacturing process has been completed, is transferred to the wafer container 10 awaiting in the EFEM 100. In more detail, when the inside of the EFEM 100 is in a vacuum state near a vacuum atmosphere of the transfer chamber 210, the first door 141 is opened and the transfer robot 212 of the transfer chamber 210 transfers the wafer in the wafer container 10 to the process chamber 230. The process chamber 230 performs a manufacturing process of a wafer and the transfer robot 212 of the transfer chamber 210 transfers the wafer, after the manufacturing process has been completed, to the wafer container 10. When all wafers are stored in the wafer container 10 awaiting in the EFEM 100 after manufacturing processes of all the wafers have been completed, the first door 141 seals the inner space 111 by closing itself and a front side of the wafer container 10 is closed by the doorway 11 of the wafer container 10.

In operation S140, the wafer container 10 is unloaded from the EFEM 100 after purge gas is injected and filled into the EFEM 100. In more detail, the gas supply 130 may inject purge gas into the inner space 111 and the wafer container 10 and may boost the inner space 111 and the wafer container 10 to the atmospheric pressure P0 from the vacuum pressure P1. When the wafer container 10 is filled with purge gas, the second door 143 is opened to carry out the wafer container 10.

According to an example embodiment, the EFEM 100 may make the wafer container 10 await in the inner space 111 in a vacuum state until a manufacturing process of a wafer has been completed. The EFEM 100 may remove residual gas or moisture in the wafer container 10 by making the wafer container 10 await in the inner space 111 in a vacuum state, and thus, a wafer in the wafer container 10 may be prevented from being contaminated by moisture or contaminants absorbed in the wafer container 10 as the moisture or contaminants are emitted from the wafer container 10.

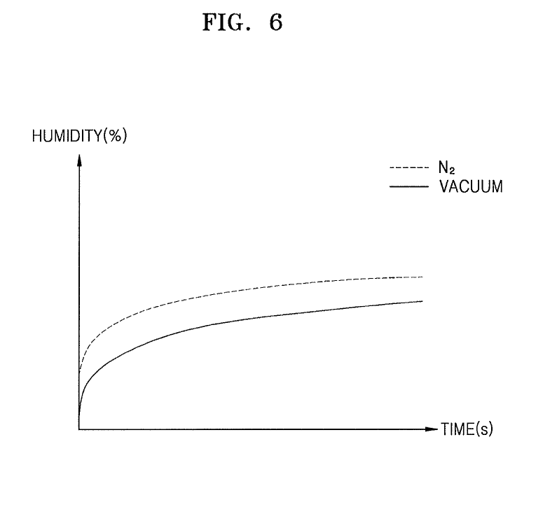

FIG. 6 is a graph showing humidity change in the wafer container 10 when the wafer container 10 is exposed to external air in an atmospheric pressure state after awaiting in the EFEM 100. FIG. 6 shows respective humidity changes in the wafer container 10 when the wafer container 10 is exposed to external air in an atmospheric pressure state after awaiting in the inner space 111 filled with nitrogen, and when the wafer container 10 is exposed to external air in an atmospheric pressure state after awaiting in the inner space 111 in a vacuum state.

Referring to FIG. 6 as well as FIG. 1, it can be seen that residual moisture in the wafer container 10 is much less when the wafer container 10 awaits in the inner space 111 in a vacuum state. For example, compared to blocking external air by filling the wafer container 10 with nitrogen gas, inert gas, or CDA, contamination of the wafer container 10 may be efficiently removed by maintaining the inside of the EFEM 100 in a vacuum state.

In particular, the wafer container 10 formed of materials easily absorbing moisture or contaminants may require frequent replacement or a cleaning and dry operation. In contrast, the EFEM 100 according to the present example embodiment may remove contamination of the wafer container 10 during a manufacturing process. Thus, costs of frequent replacement or a cleaning and dry operation of the wafer container 10 may be reduced.

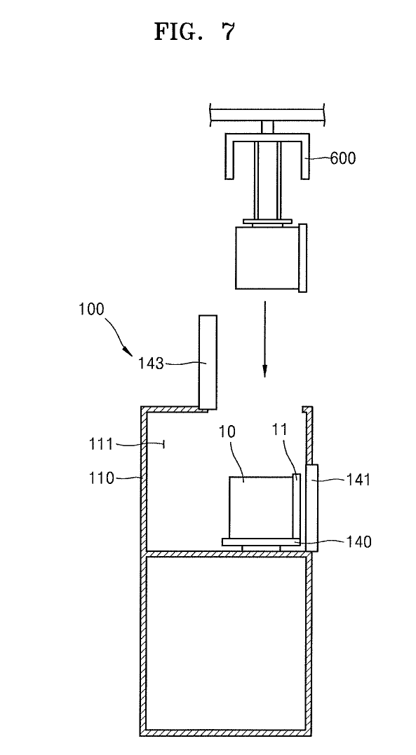

FIG. 7 is a cross-sectional view showing a process of loading or unloading the wafer container 10 into or from the EFEM 100 through a ceiling transferring device 600, according to an example embodiment.

Referring to FIG. 7, the ceiling transferring device 600 may transfer the wafer container 10 along a rail. For example, the ceiling transferring device 600 may include an overhead hoist transport (OHT). The ceiling transferring device 600 may load or unload the wafer container 10 into/from the EFEM 100 by raising or lowering the wafer container 10.

In order to load the wafer container 10, the EFEM 100 may open the second door 143 on an upper portion of the chamber 110, and the ceiling transferring device 600 may attach the wafer container 10 on a stage 140 provided on a bottom surface of the chamber 110 by lowering the wafer container 10. The doorway 11 to the wafer container 10 may be on the stage 140 to face the first door 141. The stage 140 may advance the wafer container 10 in such a manner that the wafer container 10 is adhered to the first door 141. Next, the second door 143 may be closed to shield the inner space 111 from the outside, and the EFEM 100 may form vacuum pressure by exhausting gas in the inner space 111.

In order to unload the wafer container 10, the EFEM 100 may open the second door 143, and the ceiling transferring device 600 may mount and raise the wafer container 10 in the chamber 110. Inflow of external air into the wafer container 10 may be prevented by filling the wafer container 10 with nitrogen gas, inert gas, or CDA before opening the second door 143, and thus, contamination of a wafer in the wafer container 10 due to exposure to external air may be reduced or prevented.

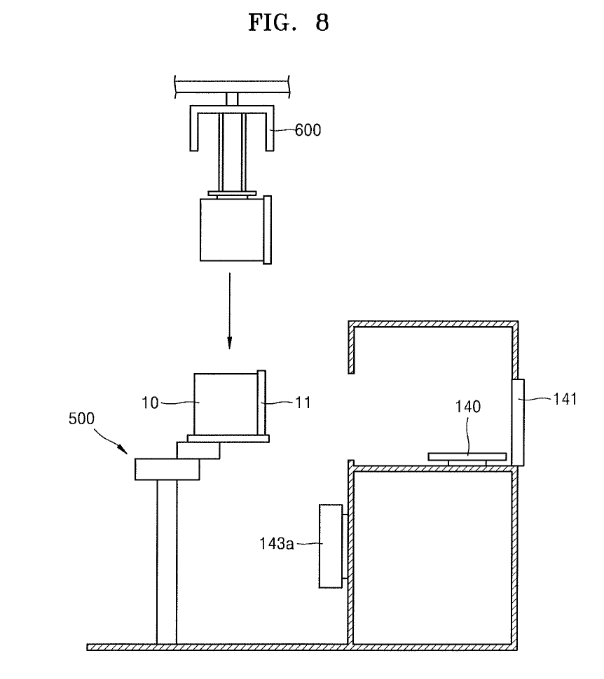

FIG. 8 is a cross-sectional view showing a process of loading or unloading the wafer container 10 into or from the EFEM 100 through a ceiling transferring device 600, according to an example embodiment.

Referring to FIG. 8, the semiconductor manufacturing apparatus 1000 may include an external transfer robot 500 to load or unload the wafer container 10 into/from the EFEM 100. The ceiling transferring device 600 may transfer the wafer container 10 along a rail, and lower and place the wafer container 10 on the external transfer robot 500, or mount and raise the wafer container 10 on the external transfer robot 500.

In more detail, in order to load the wafer container 10, the EFEM 100 may open a second door 143a on a side of the chamber 110, and the external transfer robot 500 may attach the wafer container 10 transferred by the ceiling transferring device 600 on the stage 140 provided on a bottom surface of the chamber 110. Next, the first door 141 may be closed to shield the inner space 111 from the outside.

In order to unload the wafer container 10, the EFEM 100 may open the second door 143a, and the external transfer robot 500 may transfer the wafer container 10 on the stage 140 in the chamber 110 to the outside of the chamber 110, and the ceiling transferring device 600 may mount and raise the wafer container 10 on the external transfer robot 500.

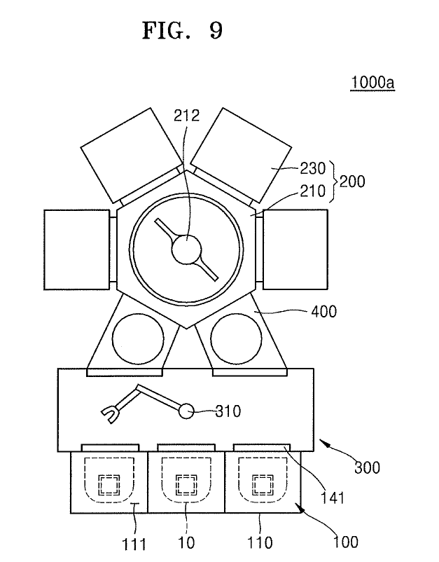

FIG. 9 is a plan view of a semiconductor manufacturing apparatus 1000a according to an example embodiment. The semiconductor manufacturing apparatus 1000a of FIG. 9 is similar to the semiconductor manufacturing apparatus 1000 of FIG. 1 except that the semiconductor manufacturing apparatus 1000a further includes a transfer module 300 and a load lock chamber 400. In FIG. 9, like reference numerals in FIG. 1 denote like elements, and therefore, detailed descriptions thereof will not be repeated below.

Referring to FIG. 9, the semiconductor manufacturing apparatus 1000a may include the EFEM 100, the transfer module 300, the load lock chamber 400, and the manufacturing process equipment 200.

The EFEM 100 may include the chamber 110 providing the inner space 111 where the wafer container 10 is held and may adjust the inner space 111 of the chamber 110 to first vacuum pressure or atmospheric pressure. The EFEM 100, in order to boost first vacuum pressure in the inner space 111 of the chamber 110 and the wafer container 10 to atmospheric pressure, may fill the inner space 111 and the wafer container 10 with, for example, nitrogen gas, inert gas, or CDA. Also, the EFEM 100 may maintain pressure of the inner space 111 with first vacuum pressure during a manufacturing process of a wafer. The EFEM 100 may forcibly exhaust gas of the inner space 111 to decompress atmospheric pressure of the inner space 111 of the chamber 110 to first vacuum pressure.

The EFEM 100 may maintain pressure of the inner space 111 at first vacuum pressure that is higher than a vacuum atmosphere in the manufacturing process equipment 200 but lower than external pressure, for example, atmospheric pressure. As a result, residual gas or moisture in the wafer container 10 awaiting in the EFEM 100 and wafers in the wafer container 10 may be removed. Decompression of the inner space 111 of the EFEM 100 to a vacuum atmosphere of the manufacturing process equipment 200 may not be needed. Contamination of the wafer container 10 and the wafers may be sufficiently removed without reducing the productivity of the semiconductor manufacturing apparatus 1000a according to a process condition.

The transfer module 300 may be disposed in the rear of the EFEM 100. The transfer module 300 may include a freely rotatable transfer robot 310 to load or unload the wafers in the wafer container 10 awaiting in the EFEM 100. The transfer robot 310 of the transfer module 300 may transfer an unprocessed wafer in the wafer container 10 to the load lock chamber 400 and may transfer a wafer awaiting in the load lock chamber 400 after a manufacturing process has been completed in the manufacturing process equipment 200 to the wafer container 10.

In some example embodiments, the transfer module 300 may maintain its inside in a vacuum state in order to prevent a wafer from being exposed to external air and contaminated while the transfer robot 310 of the transfer module 300 transfers the wafer. For example, the transfer module 300 may maintain pressure of a sealable space of its inside in first vacuum pressure.

The EFEM 100 may adjust pressure in the chamber 110 to be identical to that in the transfer module 300 to prevent a change in pressure of the transfer module 300 when the first door 141 is opened to transfer a wafer.

The load lock chamber 400 may be disposed between the transfer module 300 and the manufacturing process equipment 200. The load lock chamber 400 may adjust its internal pressure to first or second vacuum pressure to prevent a change in the transfer module 300 and the transfer chamber 210 of the manufacturing process equipment 200. As described above, second vacuum pressure indicates pressure of the manufacturing process equipment 200, and first vacuum pressure indicates pressure between second vacuum pressure and atmospheric pressure. A buffer stage, in which wafers are temporarily disposed, may be in the load lock chamber 400, and a wafer transferred by the transfer robot 310 of the transfer module 300 awaits in the buffer stage while pressure of the load lock chamber 400 is adjusted.

The load lock chamber 400 may receive an unprocessed wafer from the transfer robot 310 of the transfer module 300 by forming a vacuum atmosphere near the transfer module 300 when the transfer robot 310 of the transfer module 300 loads or unloads a wafer. The load lock chamber 400 may receive a wafer after a manufacturing process from the transfer robot 212 of the transfer module 210 by forming a vacuum atmosphere near the transfer chamber 210 when the transfer robot 212 of the transfer chamber 210 of the manufacturing process equipment 200 loads or unloads a wafer.

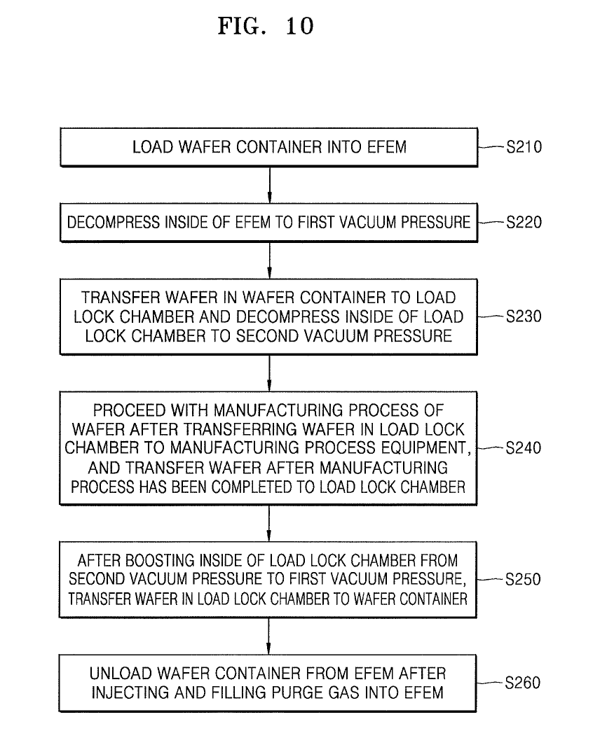

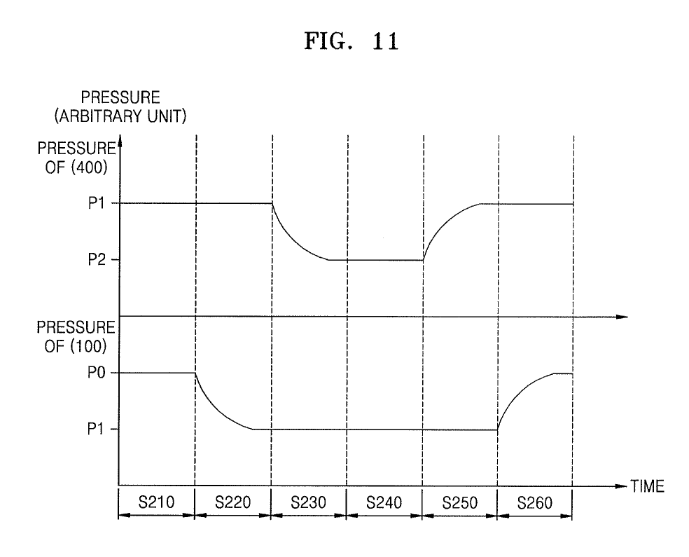

Hereinafter, with reference to FIGS. 10 and 11 as well as FIG. 9, an operation method of the semiconductor manufacturing apparatus 1000a including the EFEM 100 will be described. FIG. 10 is a flowchart of an operation method of the semiconductor manufacturing apparatus 1000a according to an example embodiment. FIG. 11 is a graph showing pressure change in the EFEM 100 and the load lock chamber 400 at each operation of the operation method of the semiconductor manufacturing apparatus 1000a of FIG. 10.

In operation S210, the wafer container 10 is loaded into the EFEM 100. The inner space 111 may be in an atmospheric pressure P0 state while the wafer container 10 is loaded into the EFEM 100.

In operation S220, the inside of the EFEM 100 is decompressed to first vacuum pressure P1. The vacuum pump 120 (of FIG. 2) exhausts gas in the inner space 111 and decompresses the inner space 111 and the inside of the wafer container 10 from the atmospheric pressure P0 to the first vacuum pressure P1. Next, the first door 141 may open a front side of the wafer container 10 by opening the doorway 11 of the wafer container 10.

In operation S230, a wafer in the wafer container 10 is transferred to the load lock chamber 400 and the inside of the load lock chamber 400 is decompressed to second vacuum pressure P2. The transfer robot 310 of the transfer module 300 transfers the wafer in the wafer container 10 to the load lock chamber 400. While internal pressure of the load lock chamber 400 is decompressed, the wafer may temporarily await in a buffer stage of the load lock chamber 400.

In operation S240, a manufacturing process of a wafer proceeds after transferring a wafer in the load lock chamber 400 to the manufacturing process equipment 200, and the wafer, after the manufacturing process has been completed, is transferred to the load lock chamber 400. In more detail, when the inside of the load lock chamber 400 is decompressed to second vacuum pressure P2 near a vacuum atmosphere of the transfer chamber 210, the transfer robot 212 of the transfer chamber 210 transfers the wafer in the load lock chamber 400 to the process chamber 230. The process chamber 230 performs a manufacturing process of a wafer and the transfer robot 212 of the transfer chamber 210 transfers the wafer, after the manufacturing process has been completed, to the load lock chamber 400.

In operation S250, after the inside of the load lock chamber 400 is boosted from the second vacuum pressure P2 to the first vacuum pressure P1, the wafer in the wafer container 400 is transferred to the wafer container 10 awaiting in the EFEM 100. In more detail, when the inside of the load lock chamber 400 is boosted to the first vacuum pressure P1 near a vacuum atmosphere of the transfer module 300, the transfer robot 310 of the transfer module 300 transfers the wafer in the load lock chamber 400 to the wafer container 10. When all wafers are stored in the wafer container 10 awaiting in the EFEM 100 by the transfer robot 310 of the transfer module 300 after manufacturing processes of all the wafers have been completed, the first door 141 seals the inner space 111 by closing itself and a front side of the wafer container 10 is closed by the doorway 11 of the wafer container 10.

In operation S260, the wafer container 10 is unloaded from the EFEM 100 after purge gas is injected and filled into the EFEM 100. In more detail, the gas supply 130 (of FIG. 2) may inject purge gas into the inner space 111 and the wafer container 10 and may boost the inner space 111 and the wafer container 10 into the first atmospheric pressure P0 from the first vacuum pressure P1. When the wafer container 10 is filled with purge gas, the wafer container 10 is carried out from the EFEM 100.

By way of summation and review, a wafer may be transferred between pieces of unit process equipment by being mounted on a wafer container referred to as a front-opening unified pod (FOUP) in order not to be contaminated. The wafer may be transferred through an equipment front end module (EFEM) locally maintaining high cleanliness in semiconductor manufacturing equipment. However, due to high integration of a semiconductor device and microfabrication of a circuit, a wafer may be contaminated as the wafer is exposed to an external environment during a manufacturing process of the semiconductor device, in which case the semiconductor product yield and productivity of manufacturing equipment may be reduced.

As described above, embodiments may provide an equipment front end module (EFEM) capable of reducing contamination of a wafer and a wafer container during a semiconductor manufacturing process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor manufacturing apparatus, comprising:
an equipment front end module (EFEM) including a chamber having an inner space that accommodates a wafer container in which a plurality of wafers are storeable, the EFEM adjusting the inner space to first vacuum pressure or atmospheric pressure; and
manufacturing process equipment configured to transfer a wafer from the wafer container to a process chamber in which a manufacturing process of the wafer is performed, and transfer the wafer, after the manufacturing process has been completed, from the process chamber to the wafer container.

2. The semiconductor manufacturing apparatus as claimed in claim 1, wherein the EFEM is configured to make the wafer container await in the inner space at the first vacuum pressure until manufacturing processes of all wafers to be stored in the wafer container have been completed and all the wafers have been stored in the wafer container.

3. The semiconductor manufacturing apparatus as claimed in claim 1, wherein the EFEM is configured to fill the inside of the wafer container with purge gas when manufacturing processes of all wafers to be stored in the wafer container have been completed and all the wafers are stored in the wafer container.

4. The semiconductor manufacturing apparatus as claimed in claim 1, wherein the EFEM includes:
a first door opening and closing between the chamber and the manufacturing process equipment, and opening in such a manner that a wafer in the wafer container is carried out to the manufacturing process equipment or carried in the wafer container from the manufacturing process equipment;
a second door opening and closing such that the inner space is exposed to the outside, or opened such that the wafer container is carried in or carried out;
a vacuum pump configured to exhaust gas in the inner space through an exhaust port of the chamber; and
a gas supply configured to inject purge gas into the inner space such that the inner space is in an atmospheric pressure state.

5. The semiconductor manufacturing apparatus as claimed in claim 4, wherein the gas supply is configured to inject the purge gas into the wafer container through an inlet port of the wafer container.

6. The semiconductor manufacturing apparatus as claimed in claim 4, wherein the second door is disposed in an upper portion of the chamber, and the wafer container is loaded or unloaded into or from the chamber by a ceiling transferring device when the second door is opened.

7. The semiconductor manufacturing apparatus as claimed in claim 4, further comprising an external transfer robot disposed on a side of the EFEM, wherein the external transfer robot moves the wafer container received from a ceiling transferring device to inside the chamber through the second door, or provides the wafer container in the chamber to the ceiling transferring device by moving the wafer container to outside the chamber through the second door.

8. The semiconductor manufacturing apparatus as claimed in claim 4, wherein the purge gas is nitrogen gas, inert gas, or clean dry air (CDA).

9. The semiconductor manufacturing apparatus as claimed in claim 1, further comprising:
a transfer module disposed in the rear of the EFEM, and including a transfer robot configured to carry out a wafer from the wafer container or carry a wafer into the wafer container; and
a load lock chamber disposed between the transfer module and the manufacturing process equipment, and configured to adjust internal pressure to first vacuum pressure or second vacuum pressure that is lower than the first vacuum pressure.

10. The semiconductor manufacturing apparatus as claimed in claim 9, wherein the transfer module is configured to have a sealable space maintained at the first vacuum pressure.

11. The semiconductor manufacturing apparatus as claimed in claim 9, wherein the transfer robot in the transfer module directly transfers a wafer in the load lock chamber to the wafer container awaiting in the EFEM.

12. The semiconductor manufacturing apparatus as claimed in claim 1, wherein the EFEM includes a plurality of chambers capable of accommodating a plurality of wafer containers, respectively.

13. An equipment front end module (EFEM), comprising:
a chamber having an inner space that accommodates a wafer container in which a plurality of wafers is storable;
a first door opening and closing between manufacturing process equipment and the chamber, and opening in such a manner that a wafer in the wafer container is directly carried out to the manufacturing process equipment or directly carried into the wafer container from the manufacturing process equipment;
a second door opening and closing such that the inner space is exposed to the outside, or opening such that the wafer container is carried in or carried out;
a vacuum pump configured to exhaust gas in the inner space through an exhaust port of the chamber; and
a gas supply configured to inject purge gas into the inner space such that the inner space is in an atmospheric pressure state.

14. The EFEM as claimed in claim 13, wherein:
the vacuum pump is configured to exhaust gas in the inner space in such a manner that pressure of the inner space is maintained at vacuum pressure until a manufacturing processes of all wafers to be stored in the wafer container have been completed and all the wafers have been stored in the wafer container, and
the gas supply is configured to inject the purge gas into the wafer container after all the wafers have been stored in the wafer container.

15. The EFEM as claimed in claim 13, wherein the gas supply is configured to simultaneously inject the purge gas into the inner space and the inside of the wafer container in such a manner that the inner space and the inside of the wafer container are adjusted to have atmospheric pressure.

16. An equipment front end module (EFEM), comprising:
a wafer container chamber, the wafer container chamber being configured to receive a wafer container that contains a plurality of wafers;
a wafer container door, the wafer container door opening and closing the wafer container chamber to an ambient atmosphere, the wafer container door passing the wafer container therethrough into and out of the wafer container chamber; and
a wafer door, the wafer door opening and closing the wafer container chamber to a process equipment, the wafer door passing a wafer from the wafer container therethrough into and out of the wafer container, wherein:
the wafer container is configured to maintain an atmospheric pressure different from the ambient atmosphere and different from the process equipment.

17. The EFEM as claimed in claim 16, wherein the wafer door directly communicates between a wafer holding space in the wafer container chamber and a wafer processing space in the process equipment.

18. The EFEM as claimed in claim 16, wherein a single wafer is transportable through the wafer door, the wafer container remaining in the wafer container chamber.

19. The EFEM as claimed in claim 16, wherein the wafer container door is in a top of the EFEM such that the wafer container passes through the wafer container door in a vertical direction, and the wafer door is in a side of the EFEM such that the wafer passes through the wafer door in a horizontal direction.

20. The EFEM as claimed in claim 16, wherein the wafer container chamber is configured to maintain a substantially constant vacuum during processing of all of the wafers in the wafer container by the process equipment.
